(19) United States
(12) Patent Application Publication
(10) Pub. No.: US 2017/0077436 A1
(43) Pub. Date: Mar. 16, 2017

(54) DISPLAY PANEL, DISPLAY APPARATUS AND METHOD OF MANUFACTURING DISPLAY PANEL

(71) Applicant: SONY CORPORATION, TOKYO (JP)

(72) Inventors: JIANGLIN YUE, TOKYO (JP); EIGO KUBOTA, TOKYO (JP)

(21) Appl. No.: 15/126,060

(22) PCT Filed: Jan. 29, 2015
(86) PCT No.: PCT/JP2015/052438

§ 371 Date: Sep. 14, 2016

(30) Foreign Application Priority Data
Mar. 25, 2014 (JP) 2014-061925

(51) Int. Cl. H01L 51/52; H01L 27/32; G06F 3/147; G09G 3/32; G06F 3/14; G09F 9/33; H01L 51/56

(52) U.S. Cl. CPC H01L 51/525; G09F 9/33; H01L 27/3293; H01L 51/5284; H01L 51/56; G09G 3/32; G06F 3/1446; G06F 3/147; G09G 2300/026

(57) ABSTRACT

The contrast of a display panel is enhanced. The display panel includes: a light-emitting-element substrate on which light-emitting elements are arranged two-dimensionally; a transparent substrate that is disposed to face the light-emitting-element substrate while keeping a predetermined interval between the light-emitting-element substrate and the transparent substrate and to transmit radiation light from the light-emitting elements; a black matrix that is disposed between the light-emitting-element substrate and the transparent substrate and that has openings at positions superposed on the light-emitting elements in plan view; a spacer disposed between the light-emitting-element substrate and the transparent substrate for regulating the interval; and a sealing resin that is disposed between the light-emitting-element substrate and the transparent substrate for bonding the light-emitting-element substrate and the transparent substrate together.

### TECHNICAL FIELD

The present technology relates to a display panel and a method of manufacturing the display panel. In particular, it relates to a display panel for displaying by light-emitting elements arranged two-dimensionally and a method of manufacturing the display panel.

### BACKGROUND ART

Conventionally, there is a display apparatus in which a number of small flat display panels are arranged on a common supporting substrate so as to constitute a large screen. Such a display apparatus is called a tiling-type display apparatus and has been widely used as a large display apparatus.

For example, a tiling-type display apparatus has been proposed, in which, to make a display apparatus having a large screen, a large number of display panels including organic EL elements arranged on a substrate two-dimensionally are bonded to a transparent substrate which also serves as a sealing substrate provided with a black matrix(e.g., see Patent Document 1).

### CITATION LIST

### Patent Document

Patent Document 1: Japanese Patent Application Laid-Open No. 2002-372928

### SUMMARY OF THE INVENTION

Problems to be Solved by the Invention

Such a tiling-type display apparatus is often used outdoors, and thus high contrast is required. To enhance the contrast, a black matrix is used for the display apparatus. The black matrix has openings that allow radiation light from the light-emitting elements to pass. For obtaining better contrast, reducing the sizes of the openings is effective. However, when the size of the opening is reduced and the display apparatus is viewed from an oblique direction, a phenomenon in which normal display is not obtained, that is, so-called vignetting becomes a problem. This is a phenomenon that occurs because the radiation light from the light-emitting element is blocked by the black matrix.

In order to reduce the area of the openings of the black matrix without causing vignetting, the distance between the black matrix and the light-emitting elements needs to be shortened. Normally, for ease of fabrication, the black matrix is formed on a transparent substrate facing the light-emitting-element substrate provided with light-emitting elements. To shorten the distance between the black matrix and the light-emitting elements, the interval between these substrates needs to be reduced. Further, considering that the light-emitting elements or the like are present between the substrates, the interval between the substrates needs to be regulated to have a short and constant distance.

However, in the above conventional technology, when a large number of display panels are bonded to the transparent substrate, the interval between each of the display panels and the transparent substrate cannot be constant. Accordingly, a problem that it is impossible to reduce the area of the openings of the black matrix is caused.

The present technology has been created in view of such circumstances, and an object thereof is to regulate the distance between the substrate provided with light-emitting elements and the black matrix to keep the distance short and to enhance the contrast of the display panel.

### Solutions to Problems

The present technology was made to solve the above problem, and a first aspect of the present technology is a display panel including: a light-emitting-element substrate on which light-emitting elements are arranged two-dimensionally; a transparent substrate that is disposed to face the light-emitting-element substrate while keeping a predetermined interval between the light-emitting-element substrate and the transparent substrate and to transmit radiation light from the light-emitting elements; a black matrix that is disposed between the light-emitting-element substrate and the transparent substrate and that has openings at positions superposed on the light-emitting elements in plan view; a spacer disposed between the light-emitting-element substrate and the transparent substrate for regulating the interval; and a sealing resin that is disposed between the light-emitting-element substrate and the transparent substrate for bonding the light-emitting-element substrate and the transparent substrate together. This brings about the effect of making the interval between the light-emitting-element substrate and the transparent substrate small and constant.

Further, in the first aspect, the spacer may be disposed between the light-emitting elements. This brings about the effect of disposing the spacer between the light-emitting elements.

Further, in the first aspect, spacers may be arranged at equal intervals. This brings about the effect of arranging the spacers evenly spaced apart from one another.

Further, in the first aspect, the spacer may be disposed on a periphery of the light-emitting-element substrate. This brings about the effect of disposing the spacer on the periphery of the light-emitting-element substrate.

Further, in the first aspect, the spacer may be provided to be offset to a center way of the light-emitting-element substrate with respect to the light-emitting elements arranged at an outermost periphery of a group of the light-emitting elements arranged two-dimensionally. This brings about the effect of offsetting the spacer to the center way of a light-emitting-element substrate with respect to light-emitting elements arranged on the outermost periphery of the light-emitting element group.

Further, in the first aspect, a plurality of spacers may be arranged and an outer periphery of a spacer group of the plurality of spacers may form a polygonal or a circular shape. This brings about the effect of forming the outer periphery of the spacer group in a polygonal or circular shape.

Further, in the first aspect, the spacer may be constituted by a columnar resin. This brings about the effect of being able to precisely regulate the interval between the light-emitting-element substrate and the transparent substrate.

Further, in the first aspect, the sealing resin may be a resin having photocurability. This brings about the effect of being able to cure the sealing resin partially.

Further, in the first aspect, the above mentioned sealing resin may be a resin having photocurability and a thermosetting property. This brings about the effect of being able to cure simultaneously the whole of the sealing resin having been partially cured.

Further, in the first aspect, a plurality of the light-emitting-element substrates may be arranged to face the transparent substrate while keeping the interval. This brings about the effect of being able to constitute a tiling-type display panel.

Further, in the first aspect, a boundary of the light-emitting-element substrates and the black matrix may be positioned to overlap each other in plan view. This brings about the effect in which the boundary between the light-emitting-element substrates is hidden by the black matrix in the tiling-type display panel.

Further, a second aspect of the present technology is a display apparatus including: a display panel including: a light-emitting-element substrate on which light-emitting elements are arranged two-dimensionally; a transparent substrate disposed to face the light-emitting-element substrate while keeping a predetermined interval between the light-emitting-element substrate and the transparent substrate and to transmit radiation light from the light-emitting elements; a black matrix that is disposed between the light-emitting-element substrate and the transparent substrate and that has openings at positions superposed on the light-emitting elements in plan view; a spacer that is disposed between the light-emitting-element substrate and the transparent substrate for regulating the interval; and a sealing resin that is disposed between the light-emitting-element substrate and the transparent substrate for bonding the light-emitting-element substrate and the transparent substrate together; and a circuit unit for supplying an image signal to the display panel. This brings about the effect of making the interval between the light-emitting-element substrate and the transparent substrate small and constant.

Further, a third aspect of the present technology is a method of manufacturing a display panel including: a black matrix forming step of forming a black matrix including openings arranged two-dimensionally, on a transparent substrate; a connecting step of connecting electrically light-emitting elements for transmitting radiation light through the transparent substrate with a wiring pattern formed on a light-emitting-element substrate so as to supply power to the light-emitting elements, after arranging the light-emitting elements on the light-emitting-element substrate at positions superposed on the openings, of the transparent substrate on which the black matrix is formed, in plan view; a spacer forming step of forming a spacer for regulating an interval between the light-emitting-element substrate and the transparent substrate on a surface, on which the light-emitting elements are arranged, of the light-emitting-element substrate on which the light-emitting elements are arranged; an applying step of applying a sealing resin for bonding the transparent substrate and the light-emitting-element substrate on the surface, on which the light-emitting elements are arranged, of the light-emitting-element substrate on which the spacer is formed; a pressure-bonding step of pressure-bonding the surface, on which the light-emitting elements are arranged, of the light-emitting-element substrate on which the sealing resin is applied to a surface, on which the black matrix is formed, of the transparent substrate on which the black matrix is formed, the surfaces facing each other, so as to sandwich the sealing resin between the light-emitting-element substrate and the transparent substrate; and a curing step of curing the sealing resin sandwiched between the light-emitting-element substrate and the transparent substrate. This brings about the effect of making the interval between the light-emitting-element substrate and the transparent substrate small and constant.

Further, in the third aspect of the present technology, the spacer may be formed by screen printing in the spacer forming step. This brings about the effect of facilitating the formation of the spacer.

Further, in the third aspect of the present technology, the method for manufacturing a display panel may further include: a provisional curing step of curing a predetermined portion of the sealing resin sandwiched between the light-emitting-element substrate and the transparent substrate to fix the light-emitting-element substrate to the transparent substrate, and a plurality of light-emitting-element substrates may be manufactured in the light-emitting-element substrate manufacturing step, the spacer may be formed on the plurality of light-emitting-element substrates in the spacer forming step, the sealing resin may be applied to the plurality of light-emitting-element substrates in the applying step, the plurality of light-emitting-element substrates may be fixed to the transparent substrate one by one by repeating the pressure-bonding step and the provisional curing step, and the sealing resin sandwiched between the plurality of light-emitting-element substrates and the transparent substrate may be cured in the curing step. This brings about the effect of constituting a tiling-type display panel.

Further, a fourth aspect of the present technology is a method for manufacturing a display panel including: a connecting step of connecting electrically light-emitting elements and a wiring pattern formed on a light-emitting-element substrate so as to supply power to the light-emitting elements after arranging the light-emitting elements on the light-emitting-element substrate two-dimensionally; a light-emitting-element-substrate-side black matrix forming step of forming a black matrix that has openings at positions superposed on the light-emitting elements in plan view on the light-emitting-element substrate on which the light-emitting elements are arranged; a spacer forming step of forming a spacer for regulating an interval between the transparent substrate that transmits emitted light of the light-emitting elements and the light-emitting-element substrate on a surface, on which the light-emitting elements are arranged, of the light-emitting-element substrate on which the black matrix is formed; an applying step of applying a sealing resin for bonding the transparent substrate and the light-emitting-element substrate together to the surface, on which the light-emitting elements are arranged, of the light-emitting-element substrate on which the spacer is formed; a pressure-bonding step of pressure-bonding the surface, on which the light-emitting elements are arranged, of the light-emitting-element substrate on which the sealing resin is applied and the transparent substrate, the surface and the transparent substrate facing each other, so as to sandwich the sealing resin between the light-emitting-element substrate and the transparent substrate; and a curing step of curing the sealing resin sandwiched between the light-emitting-element substrate and the transparent substrate. This brings about the effect of making the interval between the light-emitting-element substrate and the transparent substrate small and constant even when the black matrix is formed on the light-emitting-element substrate.

### Effects of the Invention

According to the present technology, the distance between the substrate provided with a light-emitting elements and the black matrix is shortened, and an excellent effect of being able to increase the contrast can be brought about. Note that the effects are not necessarily limited to the ones described here, they may be any one of the effects described in the present disclosure.

### BRIEF DESCRIPTION OF DRAWINGS

FIG. 1 is a diagram illustrating a configuration example of a display apparatus according to a first embodiment of the present technology.

FIG. 2 is a diagram illustrating a configuration example of a display panel according to the first embodiment of the present technology.

FIG. 3 is a diagram illustrating a configuration example of a light-emitting element and an arrangement example of light-emitting elements according to the first embodiment of the present technology.

FIG. 4 is a diagram illustrating the relationship between the interval between a light-emitting-element substrate and a transparent substrate, and an opening of the black matrix.

FIG. 5 is a cross-sectional view of a display panel for illustrating an example of the manufacturing step of the display panel.

FIG. 6 is a cross-sectional view of a display panel for illustrating an example of the manufacturing step of the display panel.

FIG. 7 is a perspective view showing a configuration example of a display apparatus according to a second embodiment of the present technology.

FIG. 8 is a cross-sectional view of a display panel for illustrating an example of the manufacturing step of the display panel.

FIG. 9 is a cross-sectional view of a display panel for illustrating an example of the manufacturing step of the display panel.

FIG. 10 is a diagram illustrating a configuration example of a display apparatus according to a modification of an embodiment of the present technology.

FIG. 11 is a cross-sectional view of a display panel for illustrating an example of the manufacturing step of the display panel.

### MODE FOR CARRYING OUT THE INVENTION

Hereinafter, modes for carrying out the present technology (hereinafter, referred to as embodiments) will be described. The descriptions will be made in the following order.

1. First embodiment (example using a single light-emitting-element substrate)

2. Second embodiment (example using a plurality of light-emitting-element substrates)

3. Modification (example forming a black matrix on the light-emitting-element substrate)

### 1. First Embodiment ps [Configuration of the Display Apparatus]

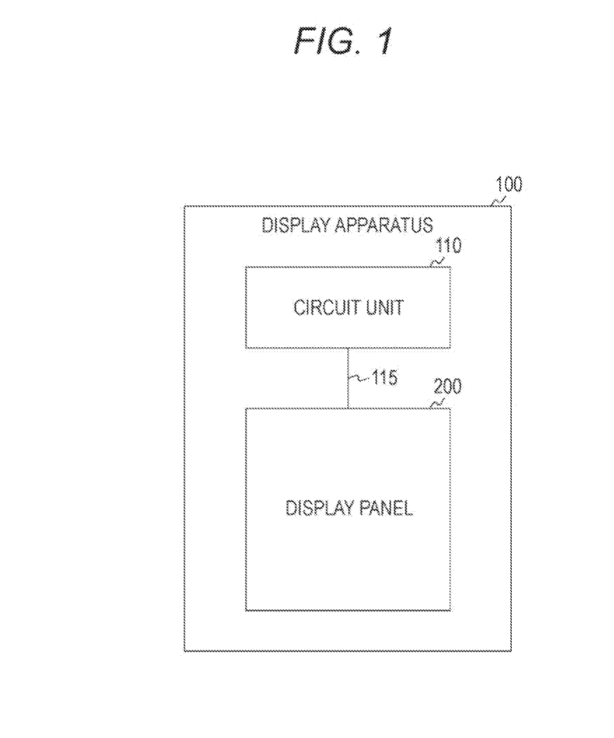

FIG. 1 is a diagram illustrating an example of the configuration of a display apparatus according to the first embodiment of the present technology. The display apparatus 100 in the figure includes a circuit unit 110, a signal cable 115, and a display panel 200. The circuit unit 110 supplies image signals to the display panel 200. The circuit unit 110 generates and outputs image signals for driving the display panel 200, on the basis of the image data signals input from an external control device or the like. The signal cable 115 is for connecting the circuit unit 110 and the display panel 200, and transmitting image signals. The display panel 200 performs display on the basis of the image signals output from the circuit unit 110. Note that the circuit unit 110 is an example of the circuit unit described in the claims. The display panel 200 is an example of the display panel described in the claims.

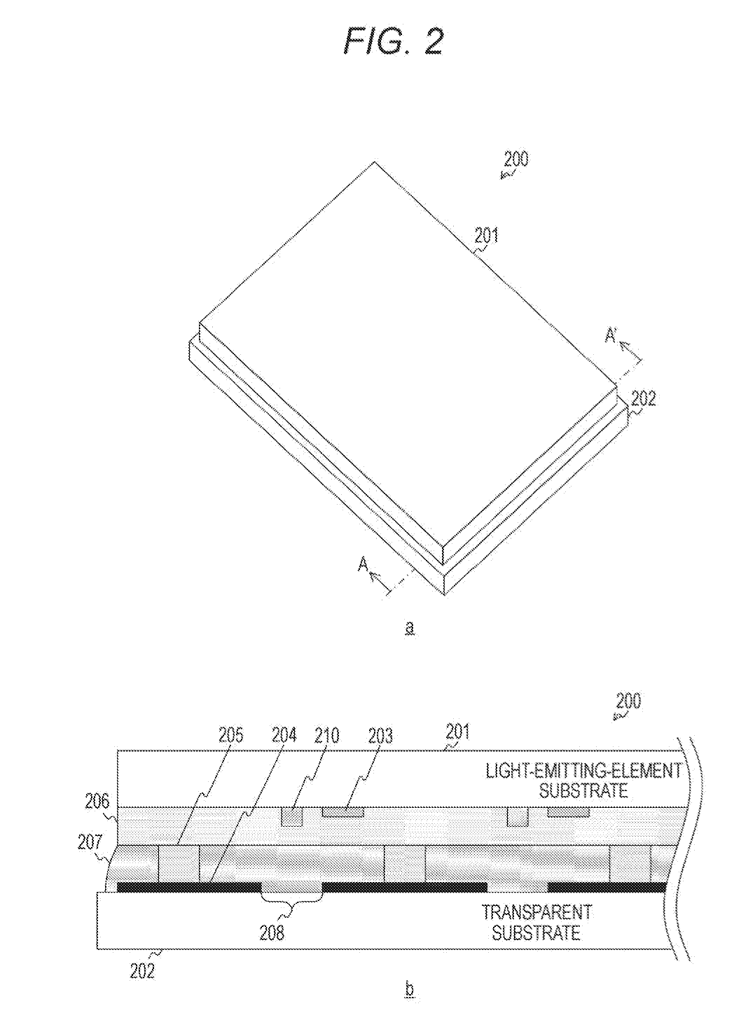

FIG. 2 is a diagram illustrating a configuration example of the display panel according to the first embodiment of the present technology. In FIG. 2, a illustrates a perspective view of the display panel, and b illustrates the cross-sectional view taken along the line A-A′ in a of FIG. 2. The display panel 200 includes a light-emitting-element substrate 201, a transparent substrate 202, a spacer 205 and a sealing resin 207. The light-emitting-element substrate 201 is a substrate for mounting thereon light-emitting elements 210 and others. The light-emitting-element substrate may be made by using a glass-containing epoxy resin, for example. The light-emitting-element substrate 201 is provided with the light-emitting elements 210, driving ICs 203 and a protective film 206. The light-emitting elements 210 are elements for emitting light for display. The driving ICs 203 are for driving the light-emitting elements 210. The protective film 206 is intended to protect the light-emitting elements 210 and the driving ICs 203 from the outside. As the protective film, a transparent resin with photocurability or a thermosetting property such as thermosetting epoxy resin may be used. In addition, the light-emitting-element substrate 201 is provided with a connector for connecting the light-emitting-element substrate 201 and a signal cable 115, and a wiring pattern for electrically connecting the connector, the driving IC 203, and the light-emitting element 210 (not shown).

The transparent substrate 202 transmits emitted light of the light-emitting elements 210 and takes out the light to the outside of the display panel from a surface opposite to the surface facing the light-emitting-element substrate 201. The transparent substrate 202 is made of glass, for example. The transparent substrate 202 is provided with a black matrix 204. The black matrix 204 enhances the contrast of the display panel and, in addition, prevents the reflection of external light, thereby improving visibility. The black matrix 204 is composed of a resin obtained by dispersing carbon black, for example. Further, the black matrix 204 is provided with openings 208 through which the emitted light of the light-emitting elements 210 passes.

The spacer 205 regulates the interval between the light-emitting-element substrate 201 and the transparent substrate 202 to maintain a predetermined interval. As the spacer 205, a resin having photocurability or a thermosetting property can be used. For example, a thermosetting epoxy resin can be used.

The sealing resin 207 adheres the light-emitting-element substrate 201 to the transparent substrate 202 for sealing. As the sealing resin 207, a transparent resin having photocurability or a thermosetting property can be used, and a resin having both the photocurability and a thermosetting property (e.g., KER-4500 manufactured by Shin-Etsu Chemical Co., Ltd.) is preferably used. This is because the resin is applicable to both a provisional curing step using photocurability and a curing step (permanent curing step) using a thermosetting property in the manufacturing step of the display panel. The manufacturing step of the display panel will be described later.

The light-emitting-element substrate 201 and the transparent substrate 202 are bonded to each other, with the surfaces thereof having the light-emitting elements 210 and the black matrix 204 respectively positioned inside. These are adhered by the sealing resin 207 in a state where the interval is restricted by the spacer 205. At this time, the light-emitting elements 210 and the openings 208 of the black matrix are aligned so that their positions are superposed on each other in plan view.

Note that the light-emitting-element substrate 201 is an example of the light-emitting-element substrate described in the claims. The transparent substrate 202 is an example of the transparent substrate described in the claims. The black matrix 204 is an example of the black matrix described in the claims. The spacer 205 is an example of the spacer described in the claims. The sealing resin 207 is an example of the sealing resin described in the claims.

### [Light-Emitting Elements and Arrangement of the Light-Emitting Elements and the Spacer]

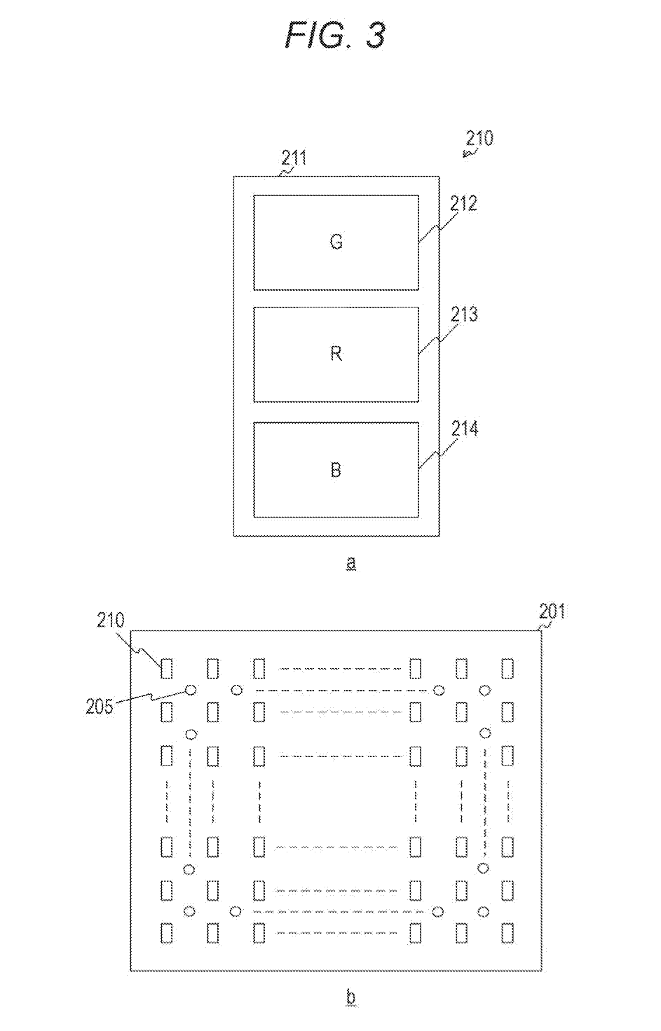

FIG. 3 is a diagram showing a configuration example of the light-emitting-element and an arrangement example of the light-emitting elements according to the first embodiment of the present technology. In FIG. 3, a is a top view showing a configuration example of the light-emitting element 210. In FIG. 3, b is a top view showing an arrangement example of the light-emitting elements 210 on the light-emitting-element substrate 201.

The light-emitting element 210 includes a substrate 211, and LEDs 212 to 214. The substrate 211 is provided with the LEDs 212 to 214 mounted thereon and electrical wiring for supplying electrical signals to these LEDs. The LEDs 212 to 214 are LEDs that emit light of G (green), R (red), and B (blue), respectively. The size of the light-emitting element 210 is 50 μm×100 μm, for example. Note that the light-emitting element 210 has a terminal that is not shown. The terminal is connected with electrical wiring described above. The electrical wiring of the light-emitting element 210 and an exterior circuit are connected via this terminal.

The light-emitting elements 210 described above are arranged two-dimensionally on the light-emitting-element substrate 201. The arrangement+is shown in b of FIG. 3. The light-emitting-element substrate 201 has a size of 100 mm×150 mm, for example, and the light-emitting elements 210 are arranged thereon in a matrix of 80×120. Note that the terminal that the substrate 211 of the light-emitting element 210 has and the wiring pattern formed on the light-emitting-element substrate 201 are electrically connected. Copper foil for example, may be used for the wiring pattern on the light-emitting-element substrate 201. Further, they can be electrically connected by soldering for example.

The spacer 205 is also arranged in the light-emitting-element substrate 201. The spacer 205 is disposed between the light-emitting elements 210. This arrangement is designed not to make the spacer overlap the light-emitting elements 210. The number of the spacers 205 may be one required to regulate the interval between the light-emitting-element substrate 201 and the transparent substrate 202. In this case, the spacers 205 are preferably positioned at regular intervals. This is for preventing the positional bias of the spacers 205. Further, as shown in b of FIG. 3, it is suitable to arrange the spacers 205 only in the periphery of the light-emitting-element substrate 201. This arrangement is designed not to interfere with encapsulation of the sealing resin 207 at the time of bonding the light-emitting-element substrate 201 and the transparent substrate 202 in the manufacturing step of the display panel described below. In b of FIG. 3, the spacers 205 are offset to the center way of the light-emitting-element substrate 201 with respect to the light-emitting elements 210 arranged at the outermost periphery of the light-emitting elements 210. That is, the spacers 205 are arranged inside the outermost peripheral line of the light-emitting elements 210 arranged two-dimensionally. Further, it is preferable that the spacers are arranged so that the outer periphery of the arranged spacers 205 forms a polygonal or circular shape. This is for applying a uniform pressure to the light-emitting-element substrate 201 at the time of the pressure bonding of the light-emitting-element substrate 201 on the transparent substrate 202 in the manufacturing step of the display panel to be described later. Note that, in b of FIG. 3, the spacer 205 is circular, but it is not limited thereto and may be square. The spacer 205 may be disposed outside the outermost peripheral line of the light-emitting elements 210.

### [Relationship Between the Interval Between the Light-Emitting-Element Substrate and the Transparent Substrate, and the Opening of the Black Matrix]

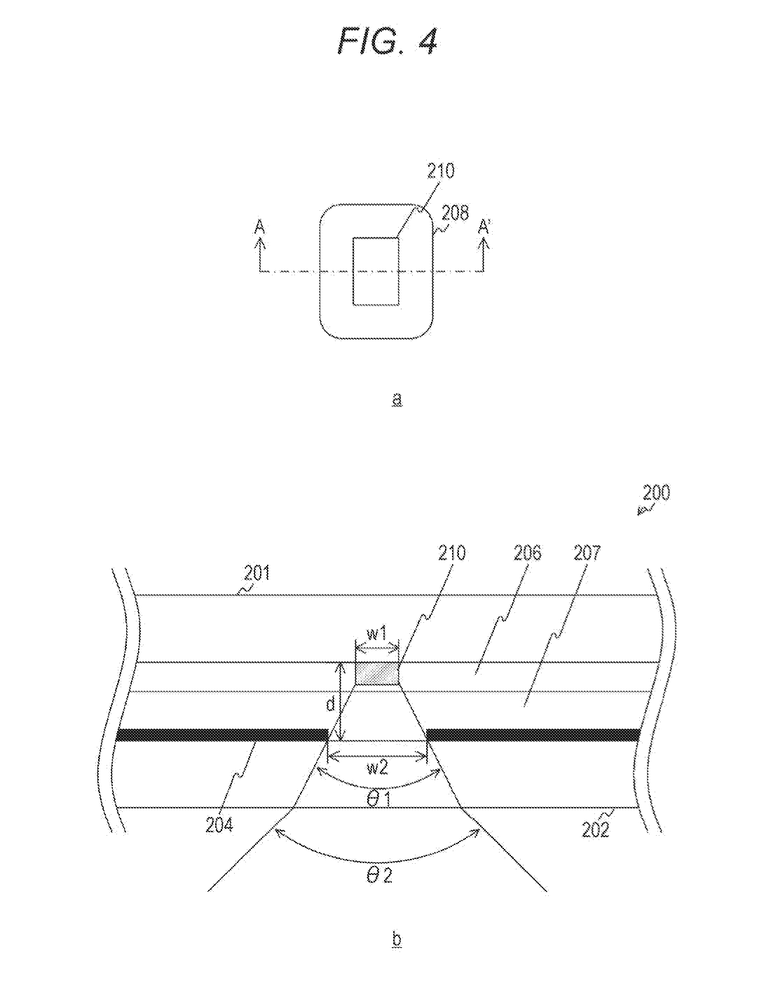

FIG. 4 is a view illustrating the relationship between the interval between the light-emitting-element substrate and the transparent substrate, and the opening of the black matrix. In FIG. 4, a is a top view of the portion of the opening 208 of the black matrix viewed from the transparent substrate 202, and b is the cross-sectional view taken along the line A-A′ in a of FIG. 4.

As shown in a of FIG. 4, the openings 208 are formed on the black matrix 204 while maintaining a predetermined distance with respect to the outline of the light-emitting element 210. As described above, to enhance the contrast, the area of the opening 208 needs to be reduced. On the other hand, the occurrence of vignetting also needs to be prevented. Here, the occurrence of vignetting is determined in the following manner. The range of 45° from the vertical direction to the transparent substrate 202 is defined as the viewing angle, and the state where a normal display cannot be performed in this range is defined as a state where the vignetting occurs. In other words, when radiation light of the light-emitting element 210 can be emitted to the outside of the display panel in the range of 90° as θ2 in b of FIG. 4, it is determined that the vignetting does not occur. Considering refraction at the boundary between the transparent substrate 202 and the air, it is assumed that θ1 in b of FIG. 4 is 45° when θ2 is 90° . At this time, the width w1 of the light-emitting element 210, the width w2 of the opening 208, and the distance d between the light-emitting element 210 and the transparent substrate have the following relationship.

w2=w1+2×d×tan(45/2)

From this equation, it can be seen that reduction of the distance d between the light-emitting element 210 and the transparent substrate is needed for reducing the size of the opening 208, that is, for reducing the width w2 in order to enhance the contrast. Note that the width wl of the light-emitting element 210 is assumed not to be changed. For example, when the widths w1 and w2 are 50 μm and 150 μm, respectively, the distance d is approximately 120 μm. The distance d includes the thickness of the protective film 206 existing on the light-emitting element 210. When this thickness is assumed to be 20 μm, the thickness of the sealing resin 207 will be 100 μm. Accordingly, the interval between the light-emitting-element substrate 201 and the transparent substrate 202 which is a predetermined interval regulated by the spacer 205 is 100 μm. Note that the refraction at the boundary surface between the protective film 206 and the sealing resin 207 and the boundary surface between the sealing resin 207 and the transparent substrate 202 is not taken into consideration because the influence is small.

### [Method of Manufacturing the Display Panel]

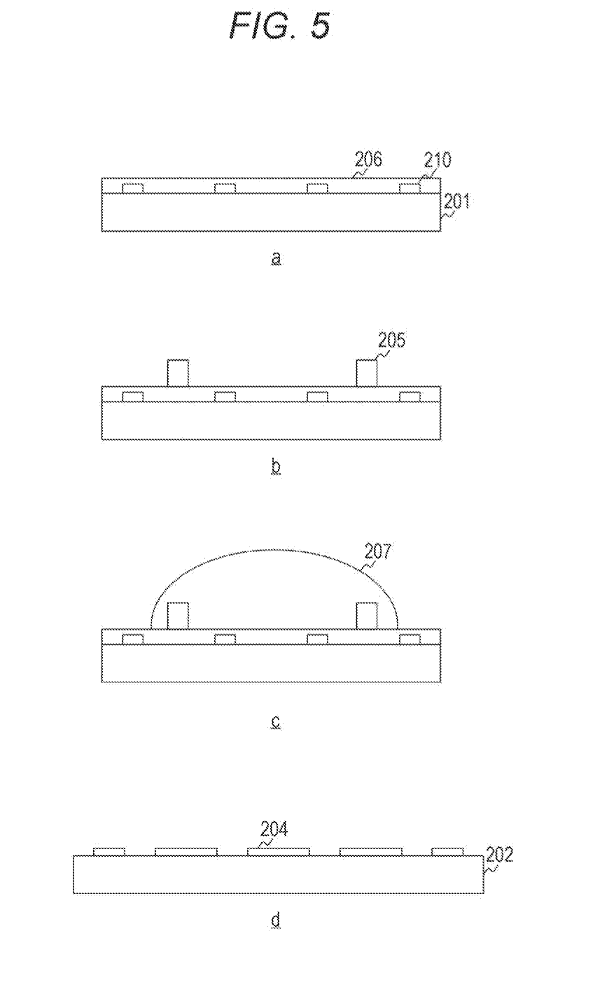

FIG. 5 is a cross-sectional view of a display panel for illustrating an example of the manufacturing step of a display panel.

First, a description of the connecting step will be given. As shown in a of FIG. 5, the light-emitting elements 210 are arranged on the light-emitting-element substrate 201. In this case, a wiring pattern on the light-emitting-element substrate 201 and a terminal of the light-emitting element 210 are connected by soldering. Note that the driving IC 203 is also subjected to a similar soldering step (not shown). After the soldering, the protective film 206 is applied and cured.

Next, the spacer forming step will be described. As shown in b of FIG. 5, the spacers 205 are formed on the surface, on which the light-emitting elements 210 are arranged, of the light-emitting-element substrate 201. The shape of the spacer 205 can be hemispherical, columnar or the like; however, a columnar shape is preferable. This is because this shape can regulate the interval between the light-emitting-element substrate 201 and the transparent substrate 202 more precisely. The spacer 205 can be formed by applying a resin by screen printing and curing the resin, for example.

Next, the applying step will be described. As shown in c of FIG. 5, the sealing resin 207 is applied on the surface, on which the light-emitting elements 210 are arranged, of the light-emitting-element substrate 201 on which the spacer 205 is formed. The application of the sealing resin can be performed with a dispenser.

Next, a black matrix forming step will be described. As shown in d of FIG. 5, the black matrix 204 is formed on the transparent substrate 202. The black matrix 204 can be formed by applying the screen printing of a resin in which carbon black is dispersed and by curing the resin, for example.

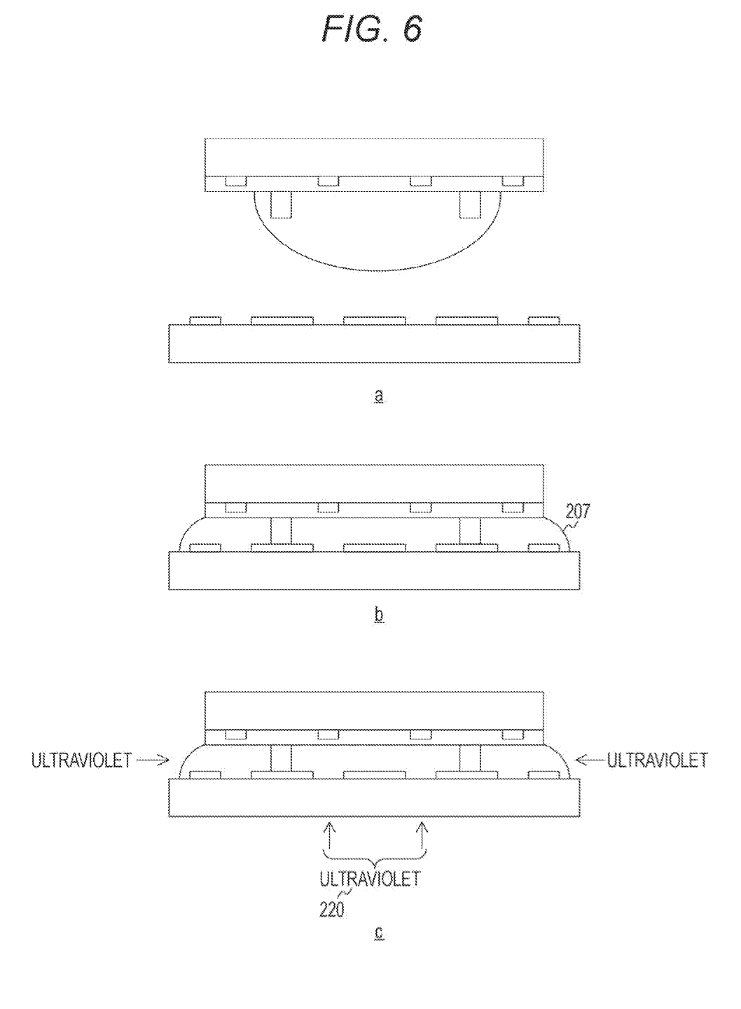

A display panel is produced by bonding the light-emitting-element substrate 201 and the transparent substrate 202 which have undergone the above steps. This step will be described with reference to FIG. 6.

FIG. 6 is a cross-sectional view of a display panel for illustrating an example of the manufacturing step of the display panel.

First, a description of the pressure-bonding step will be given. As shown in a of FIG. 6, the light-emitting-element substrate 201 coated with the sealing resin 207 is disposed to face the transparent substrate 202 on which the black matrix 204 is formed. At this time, the light-emitting-element substrate 201 is made to face the transparent substrate 202 while the surface on which the light-emitting elements 210 are disposed is faced down. Further, the position of the light-emitting element 210 is adjusted so as to be aligned with the center of the opening 208 of the black matrix. This alignment can be done by an alignment cameras provided on the transparent substrate 202 side.

Thereafter, as shown in b of FIG. 6, these substrates are pressure-bonded. In this case, these substrates are pressure-bonded by a pressure commensurate with the viscosity of the sealing resin 207 so as to uniformly spread the sealing resin 207 between the light-emitting-element substrate 201 and the transparent substrate 202. The interval between the light-emitting-element substrate 201 and the transparent substrate 202 becomes the interval regulated by the spacer 205, and the sealing resin 207 is in a state of being sandwiched between the light-emitting-element substrate 201 and the transparent substrate 202.

Next, a curing step will be described. As shown in c of FIG. 6, ultraviolet 220 is emitted to the light-emitting-element substrate 201 and the transparent substrate 202 pressed against each other, to cure the sealing resin 207. Note that, when a resin having a thermosetting property is used as the sealing resin 207, the sealing resin 207 is cured by heating.

Note that the connecting step is an example of the connecting step described in the claims. The spacer forming step is an example of the spacer forming step described in the claims. The applying step is an example of the applying step described in the claims. The black matrix forming step is an example of the black matrix forming step described in the claims. The pressure-bonding step is an example of the pressure-bonding step described in the claims. The curing step is an example of the curing step described in the claims.

Thus, according to the first embodiment of the present technology, by regulating the interval between the light-emitting-element substrate 201 and the transparent substrate 202 so as to make it short by the spacer 205, the distance between the substrate provided with light-emitting elements and the black matrix can be regulated to be short.

### 2. Second Embodiment

The aforementioned display panel uses a single light-emitting-element substrate. In contrast, the second embodiment of the present technology relates to a tiling-type display panel using a plurality of light-emitting-element substrates.

### [Configuration of the Display Apparatus]

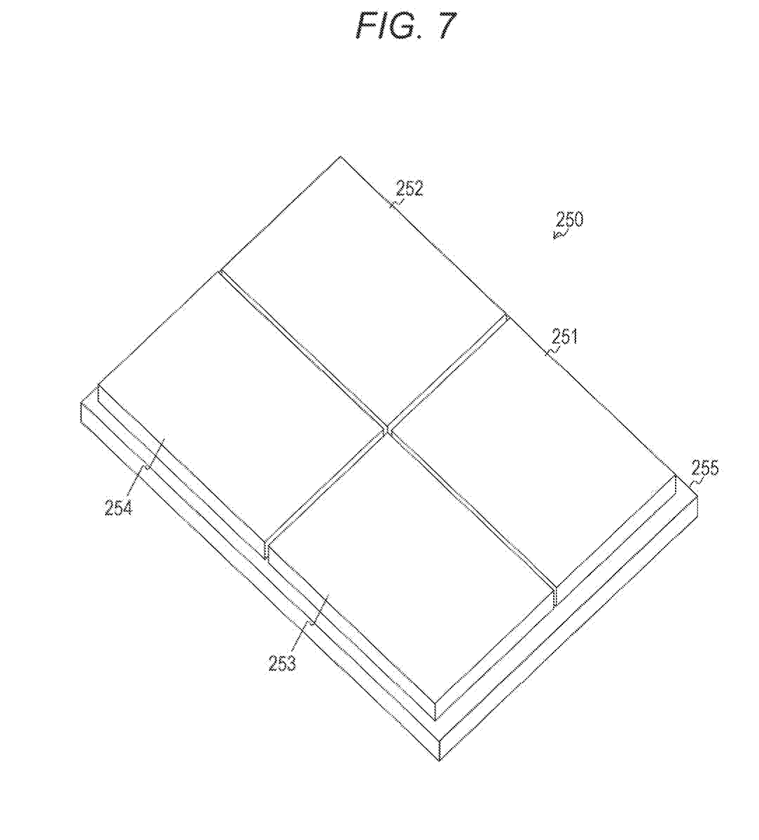

FIG. 7 is a perspective view showing a configuration example of the display apparatus according to the second embodiment of the present technology. A display panel 250 includes light-emitting-element substrates 251 to 254, and a transparent substrate 255. The display panel 250 is constituted by arranging the light-emitting-element substrates 251 to 254 on the transparent substrate 255 two-dimensionally. Further, spacers are arranged on the periphery of the light-emitting-element substrates 251 to 254 to regulate the interval between these substrates and the transparent substrate 255. Except for these features, the structures of the light-emitting-element substrates 251 to 254 and the transparent substrate 255 may be similar to those of the light-emitting-element substrate 201 and the transparent substrate 202 described above.

### [Method of Manufacturing the Display Panel]

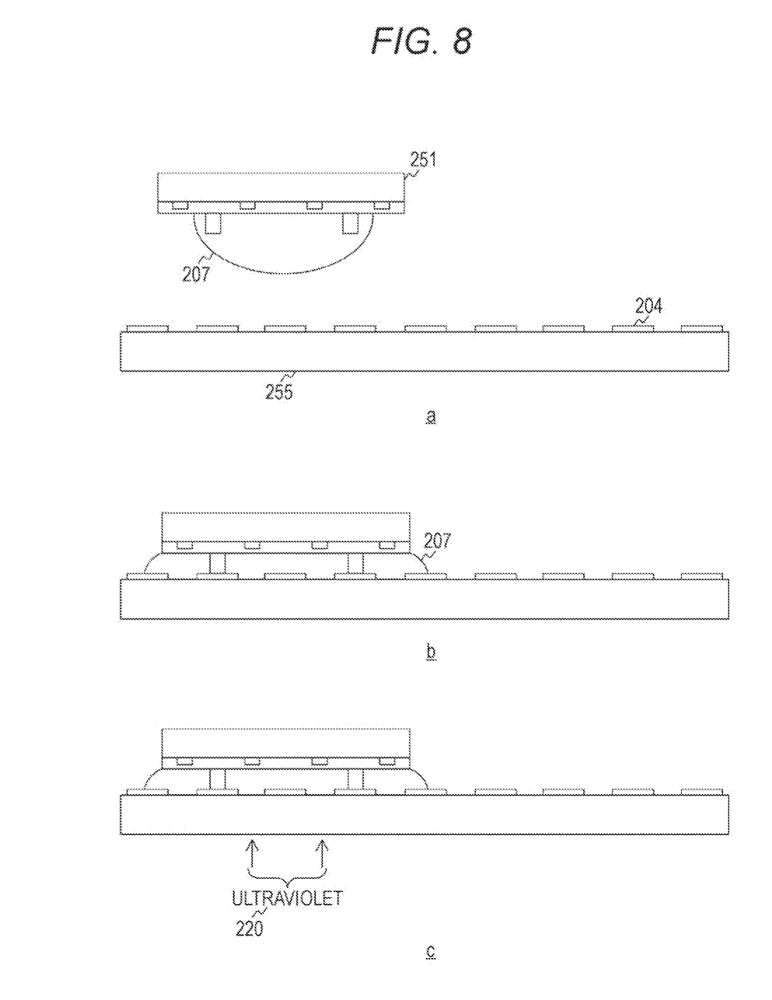

FIG. 8 is a cross-sectional view of a display panel for illustrating an example of the manufacturing step of the display panel. Note that the steps until the sealing resin 207 is applied to the light-emitting-element substrates 251 to 254 and the steps until the black matrix 204 is formed on the transparent substrate 255 are similar to the steps described with reference to FIG. 5, and thus the description thereof will not be repeated.

First, a description of the pressure-bonding step will be given. As shown in a of FIG. 8, the light-emitting-element substrate 251 coated with the sealing resin 207 is disposed to face the transparent substrate 255 on which the black matrix 204 is formed. At this time, the light-emitting-element substrate 251 is made to face the transparent substrate 255 while the surface on which the light-emitting elements 210 are arranged is faced down. Further, the position of the light-emitting element 210 is adjusted so as to be aligned with the central portion of the opening 208 of the black matrix 204.

Thereafter, as shown in b of FIG. 8, the light-emitting-element substrate 251 and the transparent substrate 255 are subjected to pressure bonding.

Next, a description of a provisional curing step will be given. As shown in c of FIG. 8, ultraviolet 220 is emitted from the transparent substrate 255 side to cure the sealing resin 207. At this time, ultraviolet 220 is irradiated only to a portion of the opening 208 of the black matrix. Accordingly, only the sealing resin 207 of the opening 208 portion is cured, and the sealing resin 207 protruding to the outside of the light-emitting-element substrate 251 as a result of the pressure-bonding step remains uncured. This is for preventing the protrusion of the sealing resin 207 from hindering the pressure bonding in the pressure-bonding steps of the remaining light-emitting-element substrates 252 to 254.

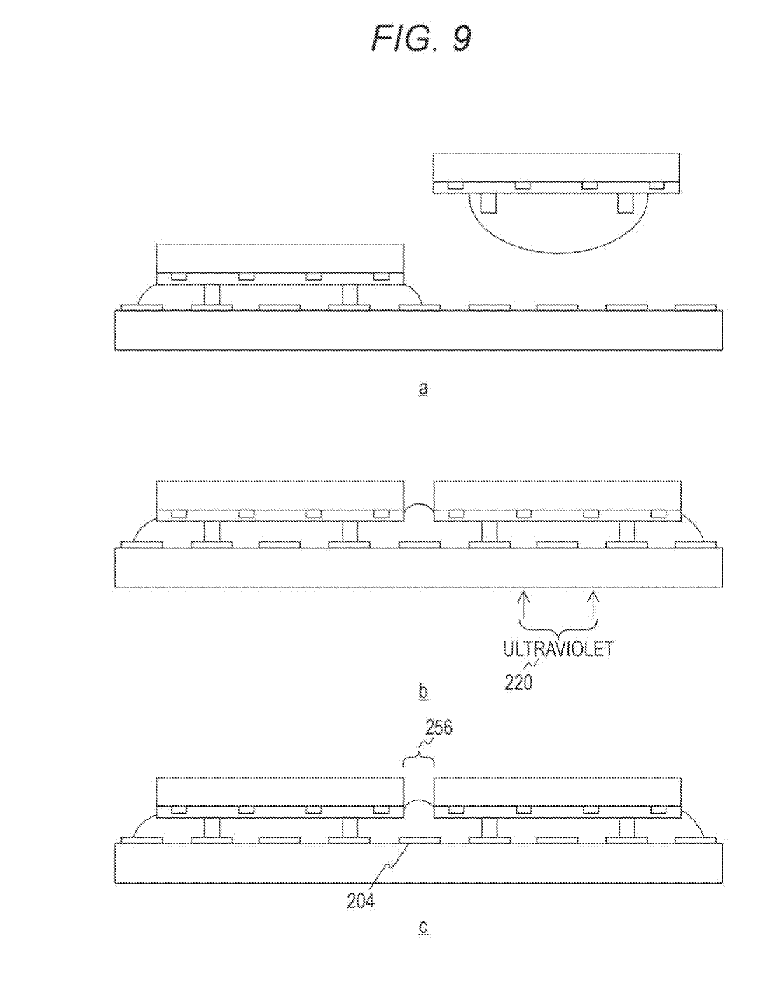

FIG. 9 is a cross-sectional view of a display panel for illustrating an example of the manufacturing step of the display panel. By repeating the pressure-bonding step (in a of FIG. 9) and the provisional curing step (in b of FIG. 9) for the light-emitting-element substrates 252 to 254, all of the light-emitting-element substrates are mounted on the transparent substrate 255.

Next, a curing step will be described. As shown in c of FIG. 9, the transparent substrate 255 mounted with the light-emitting-element substrates 251 to 254 is heated to cure the sealing resin 207. Thus, in the second embodiment of the present technology, two steps of the provisional curing step and the curing step are used selectively. In the provisional curing step, a part of the sealing resin 207 is cured, and the other light-emitting-element substrates can be mounted on the transparent substrate 255 sequentially while maintaining the state of regulating the interval between the light-emitting-element substrates 251 to 254 and the transparent substrate 255 with the spacer 205. In the subsequent curing step, the uncured sealing resin 207 can be cured collectively.

Note that, in c of FIG. 9, the boundary 256 of the light-emitting-element substrates is disposed at a position overlapping the black matrix 204 in plan view. With such a configuration, it is possible to hide the boundary 256 as viewed from the display surface of the panel and to improve display quality. Note that the provisional curing step is an example of the provisional curing step described in the claims.

Thus, according to the second embodiment of the present technology, even when the display panel is of the tiling type using a plurality of light-emitting-element substrates, the interval between the light-emitting-element substrate 201 and the transparent substrate 202 can be regulated to be short with the spacer 205. Thus, the distance between the substrate mounted with light-emitting elements and the black matrix can be regulated to be short.

### 3. Modification

In the aforementioned light emitting panel, a black matrix is formed on a transparent substrate. In contrast, in the modification of embodiment of the present technology, a black matrix is formed on the light-emitting-element substrate.

### [Configuration of the Display Apparatus]

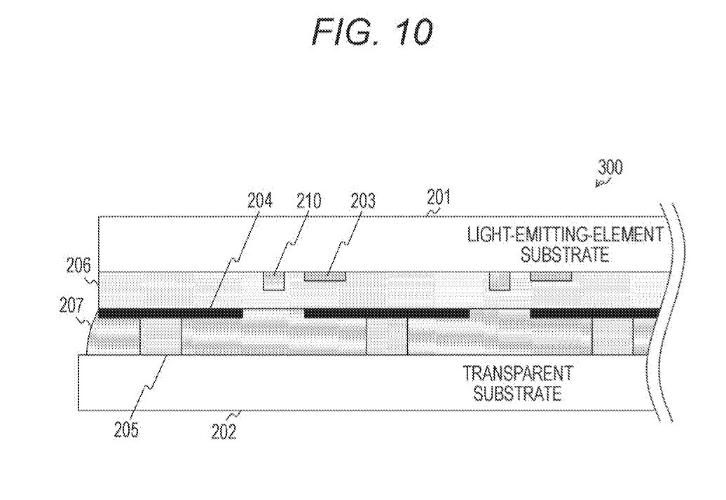

FIG. 10 is a diagram illustrating a configuration example of the display apparatus according to a modification of an embodiment of the present technology. This figure is a cross-sectional view of a display panel 300. The display panel 300 includes the black matrix 204 formed on the protective film 206 that is formed on the light-emitting-element substrate 201. The display panel can have a similar configuration to the first embodiment of the present technology except for the above structure.

### [Method of Manufacturing the Display Panel]

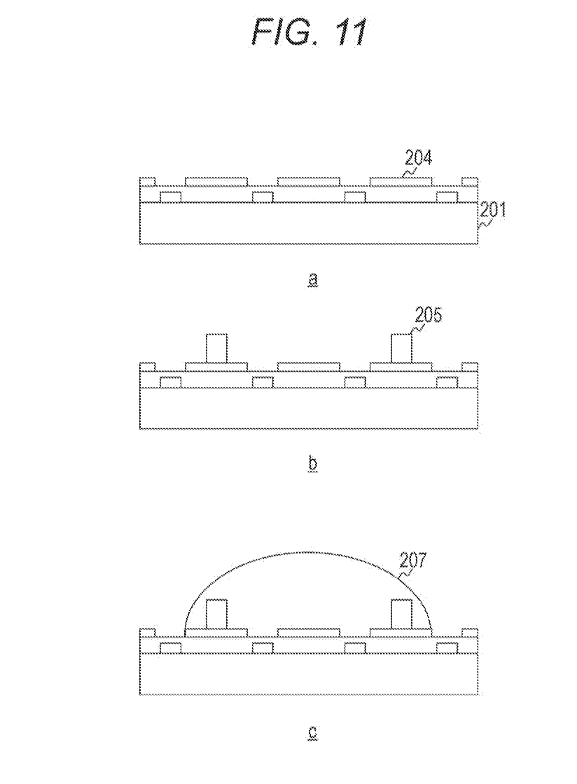

FIG. 11 is a cross-sectional view of a display panel for illustrating an example of the manufacturing step of the display panel.

First, a description of a light-emitting-element-substrate-side black matrix forming step will be given. As shown in a of FIG. 11, the black matrix 204 is formed on the surface, on which the light-emitting elements 210 are mounted, of the light-emitting-element substrate 201 after the connecting step. The black matrix 204 can be formed by a method of removing a resin at the portions of the openings 208 using photolithography after applying a resin containing dispersed carbon black, for example.

Note that the light-emitting-element-substrate-side black matrix forming step is an example of a light-emitting-element-substrate-side black matrix forming step described in the claims.

Thus, by forming the black matrix 204 on the light-emitting-element substrate 201, the distance between the light-emitting element 210 and the black matrix 204 can be shorten further. Thus, the size of the opening 208 of the black matrix can be reduced, and the contrast can be enhanced. In the modification of embodiment of the present technology, the spacer 205 does not contribute to this high contrast. However, by regulating the interval between the light-emitting-element substrate 201 and the transparent substrate 202, contact of the two substrates in the pressure-bonding step of the manufacturing step is prevented, and damage to the light-emitting elements 210 or the like can be prevented.

In this way, according to the embodiment of the present technology, by regulating the interval between the light-emitting-element substrate 201 and the transparent substrate 202 to keep the interval short with the spacer 205, the distance between the substrate mounted with light-emitting elements and the black matrix can be regulated to be short. Thus, by making the opening 208 of the black matrix small, the contrast of the display apparatus can be enhanced without causing vignetting. Further, in the case of forming the black matrix 204 on the light-emitting-element substrate 201, the distance between the light-emitting-element substrate 201 and the transparent substrate 202 can be regulated by the spacer 205. This prevents contact of the two substrates in the pressure-bonding step of the manufacturing step, and damage to the light-emitting elements 210 or the like can be prevented.

Note that the above embodiment is an example for embodying the present technology, and matters in the embodiment and matters used to specify the invention in the claims have correspondence with each other. Similarly, the matters used to specify the invention in the claims and the matters in the embodiments of the present technology to which the same names are given have correspondence with each other. However, the present technology is not limited to the embodiments and can be implemented by applying various modifications to the embodiments without departing from the spirit thereof.

Note that the effects described herein are merely illustrative, not limited thereto, and there may be other effects.

The present technology can also have the following configurations.
(1) A display panel including:

a light-emitting-element substrate on which light-emitting elements are arranged two-dimensionally;

a transparent substrate that is disposed to face the light-emitting-element substrate while keeping a predetermined interval between the light-emitting-element substrate and the transparent substrate and to transmit radiation light from the light-emitting elements;

a black matrix that is disposed between the light-emitting-element substrate and the transparent substrate and that has openings at positions superposed on the light-emitting elements in plan view;

a spacer disposed between the light-emitting-element substrate and the transparent substrate for regulating the interval; and

a sealing resin that is disposed between the light-emitting-element substrate and the transparent substrate for bonding the light-emitting-element substrate and the transparent substrate together.
(2) The display panel according to (1), wherein the spacer is disposed between the light-emitting elements.
(3) The display panel according to (1) or (2), wherein spacers are arranged at equal intervals.
(4) The display panel according to any of (1) to (3), wherein the spacer is disposed on a periphery of the light-emitting-element substrate.
(5) The display panel according to any of (1) to (4), wherein the spacer is provided to be offset to a center way of the light-emitting-element substrate with respect to the light-emitting elements arranged at an outermost periphery of a group of the light-emitting elements arranged two-dimensionally.
(6) The display panel according to any of (1) to (5), wherein a plurality of spacers are arranged and an outer periphery of a spacer group of the plurality of spacers forms a polygonal or a circular shape.
(7) The display panel according to any of (1) to (6), wherein the spacer is constituted by a columnar resin.
(8) The display panel according to any of (1) to (7), wherein the sealing resin is a resin having photocurability.
(9) The display panel according to (8), wherein the sealing resin is the resin having a thermosetting property.
(10) The display panel according to any of (1) to (9), wherein a plurality of the light-emitting-element substrates are arranged to face the transparent substrate while keeping the interval.
(11) The display panel according to (10), wherein a boundary of the light-emitting-element substrates and the black matrix are positioned to overlap each other in plan view.
(12) A display apparatus including:

a display panel including:

a light-emitting-element substrate on which light-emitting elements are arranged two-dimensionally;

a transparent substrate disposed to face the light-emitting-element substrate while keeping a predetermined interval between the light-emitting-element substrate and the transparent substrate and to transmit radiation light from the light-emitting elements;

a black matrix that is disposed between the light-emitting-element substrate and the transparent substrate and that has openings at positions superposed on the light-emitting elements in plan view;

a spacer that is disposed between the light-emitting-element substrate and the transparent substrate for regulating the interval; and

a sealing resin that is disposed between the light-emitting-element substrate and the transparent substrate for bonding the light-emitting-element substrate and the transparent substrate together; and

a circuit unit for supplying an image signal to the display panel.
(13) A method of manufacturing a display panel including:

a black matrix forming step of forming a black matrix including openings arranged two-dimensionally, on a transparent substrate;

a connecting step of connecting electrically light-emitting elements for transmitting radiation light through the transparent substrate with a wiring pattern formed on a light-emitting-element substrate so as to supply power to the light-emitting elements, after arranging the light-emitting elements on the light-emitting-element substrate at positions superposed on the openings, of the transparent substrate on which the black matrix is formed, in plan view;

a spacer forming step of forming a spacer for regulating an interval between the light-emitting-element substrate and the transparent substrate on a surface, on which the light-emitting elements are arranged, of the light-emitting-element substrate on which the light-emitting elements are arranged;

an applying step of applying a sealing resin for bonding the transparent substrate and the light-emitting-element substrate on the surface, on which the light-emitting elements are arranged, of the light-emitting-element substrate on which the spacer is formed;

a pressure-bonding step of pressure-bonding the surface, on which the light-emitting elements are arranged, of the light-emitting-element substrate on which the sealing resin is applied to a surface, on which the black matrix is formed, of the transparent substrate on which the black matrix is formed, the surfaces facing each other, so as to sandwich the sealing resin between the light-emitting-element substrate and the transparent substrate; and a curing step of curing the sealing resin sandwiched between the light-emitting-element substrate and the transparent substrate.
(14) The manufacturing method of a display panel according to (13), wherein the spacer is formed by screen printing in the spacer forming step.
(15) The method for manufacturing a display panel according to (13) or (14), further including:

a provisional curing step of curing a predetermined portion of the sealing resin sandwiched between the light-emitting-element substrate and the transparent substrate to fix the light-emitting-element substrate to the transparent substrate, wherein

a plurality of light-emitting-element substrates are manufactured in the light-emitting-element substrate manufacturing step,

the spacer is formed on the plurality of light-emitting-element substrates in the spacer forming step,

the sealing resin is applied to the plurality of light-emitting-element substrates in the applying step,

the plurality of light-emitting-element substrates are fixed to the transparent substrate one by one by repeating the pressure-bonding step and the provisional curing step, and

the sealing resin sandwiched between the plurality of light-emitting-element substrates and the transparent substrate is cured in the curing step.
(16) A method for manufacturing a display panel including:

a connecting step of connecting electrically light-emitting elements and a wiring pattern formed on a light-emitting-element substrate so as to supply power to the light-emitting elements after arranging the light-emitting elements on the light-emitting-element substrate two-dimensionally;

a light-emitting-element-substrate-side black matrix forming step of forming a black matrix that has openings at positions superposed on the light-emitting elements in plan view on the light-emitting-element substrate on which the light-emitting elements are arranged;

a spacer forming step of forming a spacer for regulating an interval between the transparent substrate that transmits emitted light of the light-emitting elements and the light-emitting-element substrate on a surface, on which the light-emitting elements are arranged, of the light-emitting-element substrate on which the black matrix is formed;

an applying step of applying a sealing resin for bonding the transparent substrate and the light-emitting-element substrate together to the surface, on which the light-emitting elements are arranged, of the light-emitting-element substrate on which the spacer is formed;

a pressure-bonding step of pressure-bonding the surface,on which the light-emitting elements are arranged, of the light-emitting-element substrate on which the sealing resin is applied and the transparent substrate, the surface and the transparent substrate facing each other, so as to sandwich the sealing resin between the light-emitting-element substrate and the transparent substrate; and

a curing step of curing the sealing resin sandwiched between the light-emitting-element substrate and the transparent substrate.

### REFERENCE SIGNS LIST

100 Display apparatus
110 Circuit unit
115 Signal cable
200, 250 and 300 Display panel
201 and 251 to 254 Light-emitting-element substrate
202 and 255 Transparent substrate
203 Driving IC
204 Black matrix
205 Spacer
206 Protective film
207 Sealing resin
208 Opening
210 Light-emitting element
211 Substrate
212-214 LED
220 Ultraviolet
256 Boundary

1. A display panel comprising:
a light-emitting-element substrate on which light-emitting elements are arranged two-dimensionally;
a transparent substrate that is disposed to face the light-emitting-element substrate while keeping a predetermined interval between the light-emitting-element substrate and the transparent substrate and to transmit radiation light from the light-emitting elements;
a black matrix that is disposed between the light-emitting-element substrate and the transparent substrate and that has openings at positions superposed on the light-emitting elements in plan view;
a spacer disposed between the light-emitting-element substrate and the transparent substrate for regulating the interval; and
a sealing resin that is disposed between the light-emitting-element substrate and the transparent substrate for bonding the light-emitting-element substrate and the transparent substrate together.

2. The display panel according to claim 1, wherein the spacer is disposed between the light-emitting elements.

3. The display panel according to claim 1, wherein spacers are arranged at equal intervals.

4. The display panel according to claim 1, wherein the spacer is disposed on a periphery of the light-emitting-element substrate.

5. The display panel according to claim 1, wherein the spacer is provided to be offset to a center way of the light-emitting-element substrate with respect to the light-emitting elements arranged at an outermost periphery of a group of the light-emitting elements arranged two-dimensionally.

6. The display panel according to claim 1, wherein the spacer includes a plurality of spacers and an outer periphery of a spacer group of the plurality of spacers forms a polygonal or a circular shape.

7. The display panel according to claim 1, wherein the spacer is constituted by a columnar resin.

8. The display panel according to claim 1, wherein the sealing resin is a resin having photocurability.

9. The display panel according to claim 8, wherein the sealing resin is the resin having a thermosetting property.

10. The display panel according to claim 1, wherein a plurality of the light-emitting-element substrates are arranged to face the transparent substrate while keeping the interval.

11. The display panel according to claim 10, wherein a boundary of the light-emitting-element substrates and the black matrix are positioned to overlap each other in plan view.

12. A display apparatus comprising:
a display panel including:
a light-emitting-element substrate on which light-emitting elements are arranged two-dimensionally;
a transparent substrate disposed to face the light-emitting-element substrate while keeping a predetermined interval between the light-emitting-element substrate and the transparent substrate and to transmit radiation light from the light-emitting elements;
a black matrix that is disposed between the light-emitting-element substrate and the transparent substrate and that has openings at positions superposed on the light-emitting elements in plan view;
a spacer that is disposed between the light-emitting-element substrate and the transparent substrate for regulating the interval; and
a sealing resin that is disposed between the light-emitting-element substrate and the transparent substrate for bonding the light-emitting-element substrate and the transparent substrate together; and
a circuit unit for supplying an image signal to the display panel.

13. A method of manufacturing a display panel comprising:
a black matrix forming step of forming a black matrix including openings arranged two-dimensionally, on a transparent substrate;
a connecting step of connecting electrically light-emitting elements for transmitting radiation light through the transparent substrate with a wiring pattern formed on a light-emitting-element substrate so as to supply power to the light-emitting elements, after arranging the light-emitting elements on the light-emitting-element substrate at positions superposed on the openings, of the transparent substrate on which the black matrix is formed, in plan view;
a spacer forming step of forming a spacer for regulating an interval between the light-emitting-element substrate and the transparent substrate on a surface, on which the light-emitting elements are arranged, of the light-emitting-element substrate on which the light-emitting elements are arranged;
an applying step of applying a sealing resin for bonding the transparent substrate and the light-emitting-element substrate on the surface, on which the light-emitting elements are arranged, of the light-emitting-element substrate on which the spacer is formed;
a pressure-bonding step of pressure-bonding the surface, on which the light-emitting elements are arranged, of the light-emitting-element substrate on which the sealing resin is applied to a surface, on which the black matrix is formed, of the transparent substrate on which the black matrix is formed, the surfaces facing each other, so as to sandwich the sealing resin between the light-emitting-element substrate and the transparent substrate; and
a curing step of curing the sealing resin sandwiched between the light-emitting-element substrate and the transparent substrate.

14. The manufacturing method of a display panel according to claim 13, wherein the spacer is formed by screen printing in the spacer forming step.

15. The method for manufacturing a display panel according to claim 13, further comprising:
a provisional curing step of curing a predetermined portion of the sealing resin sandwiched between the light-emitting-element substrate and the transparent substrate to fix the light-emitting-element substrate to the transparent substrate, wherein
a plurality of light-emitting-element substrates are manufactured in the light-emitting-element substrate manufacturing step,
the spacer is formed on the plurality of light-emitting-element substrates in the spacer forming step,
the sealing resin is applied to the plurality of light-emitting-element substrates in the applying step,
the plurality of light-emitting-element substrates are fixed to the transparent substrate one by one by repeating the pressure-bonding step and the provisional curing step, and
the sealing resin sandwiched between the plurality of light-emitting-element substrates and the transparent substrate is cured in the curing step.

16. A method for manufacturing a display panel comprising:
a connecting step of connecting electrically light-emitting elements and a wiring pattern formed on a light-emitting-element substrate so as to supply power to the light-emitting elements after arranging the light-emitting elements on the light-emitting-element substrate two-dimensionally;
a light-emitting-element-substrate-side black matrix forming step of forming a black matrix that has openings at positions superposed on the light-emitting elements in plan view on the light-emitting-element substrate on which the light-emitting elements are arranged;
a spacer forming step of forming a spacer for regulating an interval between the transparent substrate that transmits emitted light of the light-emitting elements and the light-emitting-element substrate on a surface, on which the light-emitting elements are arranged, of the light-emitting-element substrate on which the black matrix is formed;
an applying step of applying a sealing resin for bonding the transparent substrate and the light-emitting-element substrate together to the surface, on which the light-emitting elements are arranged, of the light-emitting-element substrate on which the spacer is formed;
a pressure-bonding step of pressure-bonding the surface, on which the light-emitting elements are arranged, of the light-emitting-element substrate on which the sealing resin is applied and the transparent substrate, the surface and the transparent substrate facing each other, so as to sandwich the sealing resin between the light-emitting-element substrate and the transparent substrate; and
a curing step of curing the sealing resin sandwiched between the light-emitting-element substrate and the transparent substrate.
